(19) United States
(12) Patent Application Publication
(10) Pub. No.: US 2003/0099101 A1
(43) Pub. Date: May 29, 2003

(54) Optical network unit with EMI suppression

(76) Inventors: Alan J. Skrepcinski, Plano, TX (US); Mulwa K. Mangeli, Irving, TX (US); Walter M. Hendrix, Richardson, TX (US)

Correspondence Address: Lorri W. Cooper, Esq., JONES, DAY, REAVIS & POGUE, North Point, 901 Lakeside Avenue, Cleveland, OH, 44114, US

(21) Appl. No.: 10/283,527

(22) Filed: Oct. 30, 2002

Related U.S. Application Data
(60) Provisional application No. 60/339,989, filed on Oct. 30, 2001.

(51) Int. Cl. H05K 7/14; H05K 7/18

(52) U.S. Cl. 361/796

(57) ABSTRACT

An enclosure for deterring the transmission of electromagnetic radiation therethrough comprises a housing, a door and a plurality of fingers that extend from the door. The housing has an opening for holding electronic equipment. The door is coupled to the housing and has a periphery. The housing, door, and fingers are conductive. When the door is in a closed position, the plurality of fingers on the door contact the housing.

### CROSS-REFERENCE TO RELATED APPLICATIONS

This application claims the benefit of U.S. Provisional Application No. 60/339,989, filed Oct. 30, 2002.

### FIELD OF THE INVENTION

The claimed invention relates to an enclosure for housing circuits. In particular, the invention relates to an enclosure that prevents the transmission of electromagnetic radiation through the enclosure.

### BACKGROUND

To provide consumers with increased bandwidth for transmitting and receiving telecommunications information, fiber in the loop (FITL) networks have been developed. With these networks, optical fiber carries digital information to a location close to the consumer. In FITL networks, optical network units receive digital optical signals from fiber optic cable, perform optical-to-electrical (and electric-to-optical) conversion, and distribute digital electric signals to the consumers through multiplexing or other distribution means.

Optical network units are enclosures that house circuit boards. The units are utilized to prevent the ingress or egress of electromagnetic radiation that is created by electronic parts housed within the optical network unit, or electromagnetic radiation generated outside the enclosure. The equipment must meet strict reliability standards and the enclosures must be able to protect the equipment against the elements, as well as electromagnetic radiation. A copper coating has been applied to the interior of a polymer shell to prevent electromagnetic interference, as disclosed in U.S. Pat. No. 5,896,272.

### SUMMARY

According to the invention, an enclosure for deterring the transmission of electromagnetic radiation therethrough comprises a housing, a door, and a plurality of fingers. The housing has walls and an opening for holding electronic equipment. The door is coupled to the housing and has an open position and a closed position. In the closed position, the door closes the opening in the housing. The door has walls and a periphery. The plurality of fingers extend outwardly from and are spaced around the periphery of the door. The fingers are configured to contact the walls of the housing when the door is in the closed position. The walls of the housing, walls of the door, and fingers are conductive.

In one embodiment, the housing and door each have interior walls. The plurality of fingers are positioned on the interior walls of the door and extend to contact the interior walls of the housing when the door is in the closed position. The plurality of fingers may be configured to create an interference fit with the interior walls of the housing when the door is in the closed position in order to maintain electrical coupling between the housing and the door.

In another embodiment, a method of providing an electromagnetically shielded enclosure is provided. The method utilizes the enclosure, described above, and comprises closing the door to cover the opening in the housing.

### BRIEF DESCRIPTION OF THE DRAWING FIGURES

FIG. 1 is a partial perspective view of an enclosure according to the invention;

FIG. 2 is a cross-sectional view of a portion of the enclosure of FIG. 1, taken at line 2-2.

### DETAILED DESCRIPTION

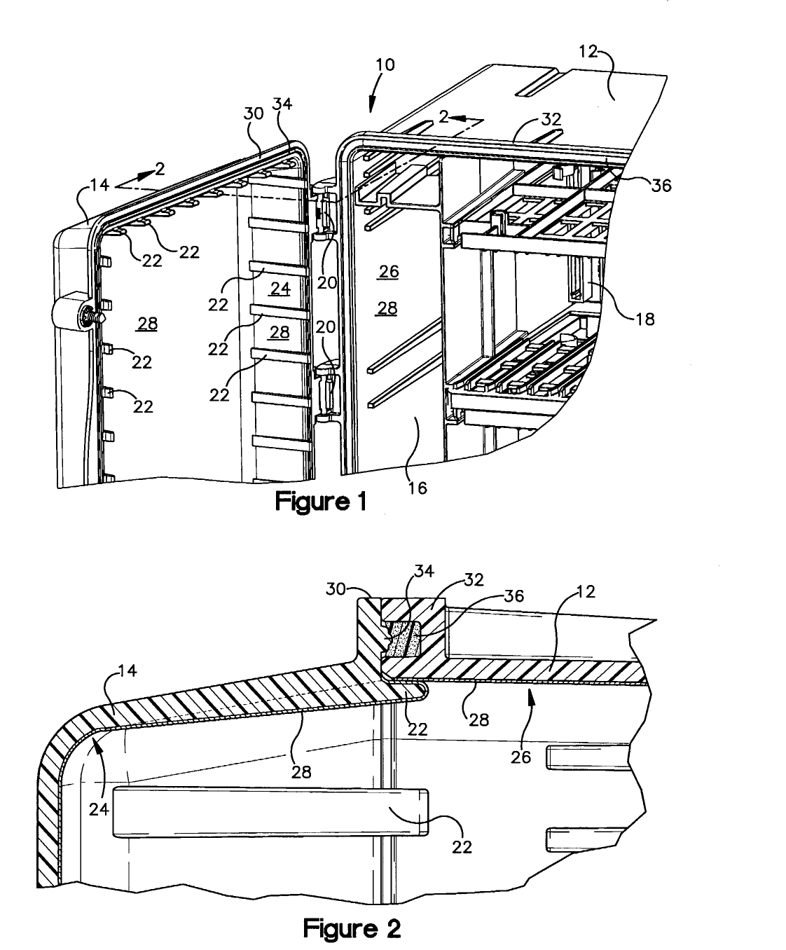

The invention relates to an optical network unit or other enclosure for housing equipment that generates electromagnetic radiation or is sensitive to electromagnetic radiation. The invention deters or prevents the ingress and egress of electromagnetic radiation from or into the enclosure. The enclosure is preferably made of plastic or another polymer, such as a polycarbonate, and is coated on the inside with copper, aluminum, or another conductive material designed to prevent the transmission of electromagnetic radiation therethrough. An example of one type of enclosure is disclosed in FIG. 1, as well as in U.S. Pat. No. 5,896,272, the disclosure of which is incorporated herein by reference in its entirety.

Referring to FIGS. 1 and 2, enclosures 10 typically have a housing or body portion 12 and a door 14. The housing 12 has an interior opening 16 for housing electronic equipment 18, such as circuit boards and wiring. The door 14 is connected to the housing 12 by hinges 20, although other types of attachment mechanisms may be utilized. Fingers 22 are positioned around the side walls 24 of the door 14 and extend outwardly from the door 14 toward the housing 12. The fingers 22 are spaced apart around the inside of the side walls 24. In a preferred embodiment, the fingers 22 are spaced in a regular pattern and in approximate 1 inch intervals. The degree of separation of the fingers 22 will depend on the size and usage of the enclosure 10. Thus, in alternative embodiments, the fingers 22 may be spaced in greater or smaller increments.

The finger 22 shown in cross-section in FIG. 2 has a thickness that varies along its length, such that the thickness is about ⅛ inch or about ¼ inch where the fingers 22 meet the housing 12 to zero where the fingers 22 transition into the wall of the door 14. The fingers 22 extend from the front wall of the door past the periphery of the door 14. In an alternative embodiment, the fingers 22 may have a cross-section with a constant thickness, such as, for example, about ⅛ inch or ¼ inch. In addition, the fingers 22 may have a length and width that differs from that shown. For example, the fingers 22 may have a width of about ¼ inch and a length of about 1 ½ inches, or a width and length that is greater or smaller. An alternative embodiment has fingers 22 that are one-half the length of the side walls 24 of the door.

The inside walls 24 of the door 14, the fingers 22, and the inside walls 26 of the housing 12 of the enclosure 10 are coated with a conductive material 28, such as copper. The fingers 22 have a length that allows then to extend into the housing 12 along each of the interior walls 26 of the housing 12. In particular, the fingers 22 preferably are shaped so that they contact the interior walls 26 of the housing 12 when the door 14 of the enclosure 10 is in its closed position. The plastic housing 12 and door 14 are designed such that the copper coated fingers 22 interfere slightly with and/or grab the copper coated walls 26 of the housing 12 when the door 14 is closed. This slight interference may result in slight flexure of the fingers 22 and spring loaded contact between the fingers 22 and the housing 12 so that the copper on the walls 26 of the housing 12 contacts the copper on the fingers 22. This contact provides electrical continuity between the copper coated walls 26 of the housing 12 and the copper coated walls 24 of the door 14, and a resulting EMI shielding effect.

The door 14 and the housing 12 each include a face or lip member 30, 32 that extends around their periphery. In particular, the door 14 has a lip member 30 that extends around the periphery of the door 14 generally perpendicular to the surrounding walls of the door 14. The housing 12 has a lip member 32 that extends around the periphery of the opening of the housing 12 and is generally perpendicular to the surrounding walls of the housing 12. A rib 34, shown being positioned on the door face member 30, may be utilized to act as a seal against a gasket 36 that is positioned on the opposing lip member 32 of the housing 12. The abutment of the rib 34 against the gasket 36 creates a seal for preventing the ingress of water, wind, or other environmental conditions that may be associated with bad weather conditions. The face member 30 of the door 14 preferably mates with the face member 32 of the housing 14 to provide a weather-tight seal. In alternative embodiments, the gasket 36 and/or standing rib 34 may be optional, since the overall design of the face members 30, 32, may be sufficient alone to provide the necessary weather-tight seal.

An EMI test was conducted to obtain engineering data to determine an acceptable finger spacing. Utilizing four frequencies above the specified limits for the equipment, in the frequency range of 233 to 700 MHz, it was determined that a maximum separation for the fingers 22 of one inch along the perimeter of the enclosure was acceptable for the particular parts that were tested.

The enclosure 10 may be manufactured using an injection molding technique and the interior surfaces of the enclosure and fingers may be coated with a conductive material utilizing known coating techniques. The fingers may be molded as part of the door, or the fingers may be separately applied. The conductive coating on the fingers should have contact with the conductive coating on the interior walls of the door in order to provide the greatest electromagnetic shielding benefit. The design disclosed herein addresses radio frequency (RF) issues without the need for a conventional electromagnetic radiation (EMI) gasket. All the EMI shielding features are molded into the injection molded door and enclosure, which results in significant cost savings over prior designs, which required a special gasket or additional parts to provide EMI shielding.

While the conductive coating has been discussed in the context of coating the interior surfaces of the parts, the conductive coating may alternatively, or in addition to, be positioned on an exterior surface of the parts. In addition, fingers may be provided on the exterior surfaces of the parts in addition to, or instead of on the interior surface of the parts.

While various features of the claimed invention are presented above, it should be understood that the features may be used alone or in any combination thereof. Therefore, the claimed invention is not to be limited to only the specific embodiments depicted herein.

Furthermore, it should be understood that variations and modifications may occur to those skilled in the art to which the claimed invention pertains. The embodiments described herein are exemplary of the claimed invention. The disclosure may enable those skilled in the art to make and use embodiments having alternative elements that likewise correspond to the elements of the invention recited in the claims. The intended scope of the invention may thus include other embodiments that do not differ or that insubstantially differ from the literal language of the claims. The scope of the present invention is accordingly defined as set forth in the appended claims.

What is claimed is:

1. An enclosure for deterring the transmission of electromagnetic radiation therethrough comprising:
a housing having at least one wall and an opening for holding electronic equipment;
a door coupled to the housing having an open position and a closed position, with the closed position closing the opening in the housing, said door having at least one wall and a periphery; and
a plurality of fingers extending outwardly from and spaced around the periphery of the door, said plurality of fingers being configured to contact the at least one wall of the housing when the door is in the closed position, wherein the at least one wall of the housing, the at least one wall of the door, and the fingers are conductive.

2. The enclosure of claim 1, wherein the housing has interior walls and the door has interior walls, and the plurality of fingers are positioned on the interior walls of the door and extend to contact the interior walls of the housing when the door is in the closed position.

3. The enclosure of claim 2, wherein the plurality of fingers are configured to create an interference fit with the interior walls of the housing when the door is in the closed position in order to maintain electrical coupling between the housing and door.

4. The enclosure of claim 1, wherein the housing, door, and fingers are a plastic material that is coated with a conductive material.

5. The enclosure of claim 4, wherein the conductive material is copper or aluminum.

6. The enclosure of claim 1, wherein the fingers are substantially evenly spaced around the periphery of the door.

7. The enclosure of claim 5, wherein the fingers are spaced in intervals of about one inch around the periphery of the door.

8. The enclosure of claim 1, wherein the fingers have a cross-section that varies along at least a portion of their length.

9. The enclosure of claim 1, wherein the fingers are resilient.

10. The enclosure of claim 1, wherein the housing is configured to house a plurality of circuit boards.

11. The enclosure of claim 1, wherein the fingers extend perpendicular to the opening of the housing.

12. The enclosure of claim 1, wherein the door has a face member and the housing opening has a face member, and the face member of the door is configured to mate with the face member of the housing opening.

13. The enclosure of claim 12, further comprising a gasket positioned on at least one of the door face member or the housing face member, said gasket being configured to seal the enclosure from adverse weather conditions.

14. A method of providing an electromagnetically shielded enclosure, comprising:
providing the enclosure of claim 1;
closing the door to cover the opening in the housing.
